(19) United States
(12) Patent Application Publication
(10) Pub. No.: US 2005/0239239 A1
(43) Pub. Date: Oct. 27, 2005

(54) Thin-film transistor and method of fabricating the same

(75) Inventors: Shoichi Takanabe, Kumamoto (JP); Tadaki Nakahori, Kumamoto (JP); Yusuke Uchida, Kumamoto (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Mitsubishi Denki Kabushiki Kaisha, Tokyo (JP)

(21) Appl. No.: 11/109,852

(22) Filed: Apr. 20, 2005

(30) Foreign Application Priority Data
Apr. 22, 2004 (JP) 2004-126690

(51) Int. Cl. H01L 21/84

(52) U.S. Cl. 438/166

(57) ABSTRACT

There is provided a thin-film transistor being capable of reducing dispersion in threshold voltage and a method of fabricating the same. The thin-film transistor includes an insulating undercoating layer formed for a substrate, a semiconductor active layer of polycrystalline silicon formed on the insulating undercoating layer, and a gate electrode formed insulated on the semiconductor active layer, the insulating undercoating layer being of a silicon oxide film layer formed using TEOS as a material and by a plasma CVD method. Preferably, the concentration of carbon atoms of the silicon oxide film layer is within a range of 6×10¹⁹ atoms/cm³ to 1×10²⁰ atoms/cm³ and the concentration of nitride atoms is not more than 3×10¹⁹ atoms/cm³.

### BACKGROUND OF THE INVENTION

1. Field of the Invention

The present invention relates to a thin-film transistor which is incorporated into a liquid crystal display device and the like and is capable of reducing dispersion in threshold voltage, and to a method of fabricating the same.

2. Description of the Background Art

In a liquid crystal display device of an active matrix method, a thin-film transistor of amorphous silicon has been widely used for a switching device of a liquid crystal display pixel, since a semiconductor active layer can be uniformly formed even on a substrate of a large area at a relatively low temperature. Recently, a thin-film transistor of polycrystalline silicon has been used due to its larger field effect mobility than a thin-film transistor of amorphous silicon. Providing a thin-film transistor of polycrystalline silicon for a switching device of a display pixel as well as a peripheral driving circuit device on the same substrate makes it possible to produce a high quality display device at reduced cost.

Such a thin-film transistor mainly employs a top gate type having a gate insulating layer and a gate electrode formed on a semiconductor active layer.

Recently, due to larger substrates and application to less expensive glass substrates, it has become more common that a polycrystalline silicon oxide film is formed by a low temperature process. In order to form silicon oxide by a low temperature process, it is necessary to use a plasma CVD (plasma chemical vapor deposition) method instead of a thermal oxidation method. Compared with a thermal oxidation method, however, a plasma CVD method has a problem that the film quality tends to be reduced due to dispersion in crystallinity of a silicon oxide film formed. This reduced film quality leads to increase and dispersion in the threshold voltage of a thin-film transistor.

As a method to reduce variation in threshold voltage and resistance in a low concentration impurity injection region as well as to provide excellent electric properties, for example, Japanese Patent laying-open No. 2000-260995 describes a method of fabricating a thin-film semiconductor device by successively forming an undercoating film and an amorphous silicon film to a predetermined film thickness on an insulating substrate in vacuum, and continuously applying laser annealing to the amorphous silicon film without being exposed to the atmosphere to make a polysilicon film.

With this method, an interface corresponding to a channel portion of a transistor is formed without being exposed to the atmosphere and a clean interface including no impurity is formed.

However, it is difficult to eliminate non-uniformity of crystallinity in a polysilicon film formed by a low temperature process by only preventing an impurity from entering from the atmosphere.

Japanese Patent laying-open No. 2000-323717 describes a thin-film transistor, wherein an insulating undercoating thin-film layer covering a glass substrate includes a silicon nitride film and a silicon oxide film covering the silicon nitride film, and a silicon oxide film has a thickness of at least 100 nm.

In this method, by making a silicon oxide film to a thickness of at least 100 nm to provide an interface between a silicon nitride film and a silicon oxide film away from a semiconductor active layer, it is possible to reduce an effect on the semiconductor active layer caused by an interfacial charge on the interface and stabilize threshold voltage for variation and dispersion in the film thickness of the silicon oxide film. However, with this method, if either a silicon nitride film or a silicon oxide film is deposited by a plasma CVD method, it is difficult to reduce variation in the threshold voltage caused by non-uniformity of crystallinity in both silicon films.

Japanese Patent laying-open No. 2002-141510 proposes a thin-film transistor having polycrystalline semiconductor of an average roughness of at least 5 nm and not more than 10 nm formed on an insulating substrate. In this method, the average roughness of a polycrystalline silicon film obtained after laser annealing is controlled by controlling a film thickness of a silicon oxide film existing on the surface of an amorphous silicon film before laser annealing. Since the average roughness can be regarded as an indicator of crystal grain size, a polycrystalline silicon oxide film having reduced dispersion in crystallinity can be formed by the above method. However, controlling a film thickness provides limited improvement of the film quality of a polycrystalline silicon film, and it is difficult to improve the film quality to a satisfactory level.

Further, Japanese Patent laying-open No. 2002-190604 proposes a thin-film transistor with each concentration of at least one impurity element present on an interface between a semiconductor thin film and a gate insulating film of not more than 3×10¹¹ atoms/cm². If an impurity diffusion barrier film and amorphous silicon are sequentially formed by a process without being exposed to the atmosphere using a plasma CVD method, for example, the concentration of an impurity on the interface between the semiconductor thin-film and the gate insulating film can be reduced while dispersion in crystallinity of polycrystalline silicon is large and it is difficult to improve the film quality of a polycrystalline silicon film to a satisfactory level.

### SUMMARY OF THE INVENTION

The present invention relates to a thin-film transistor which solves the above described problems to reduce dispersion in the threshold voltage and provide excellent display quality and reliability, and to a method of fabricating the same.

The present invention relates to a thin-film transistor including an insulating undercoating layer formed for a substrate, a semiconductor active layer of polycrystalline silicon formed on the insulating undercoating layer, and a gate electrode formed insulated on the semiconductor active layer, wherein the insulating undercoating layer include a silicon oxide film layer formed of tetraethoxysilane by a plasma CVD method.

The concentration of carbon atoms of the silicon oxide film layer is preferably within a range of 6×10¹⁹ atoms/cm³ to 1×10²⁰ atoms/cm³.

The concentration of nitride atoms of the silicon oxide film layer is preferably not more than 3×10¹⁹ atoms/cm³.

It is especially preferable that the concentration of carbon atoms of the silicon oxide film layer is within a range of 6×10¹⁹ atoms/cm³ to 1×10²⁰ atoms/cm³ while the concentration of nitride atoms is set to not more than 3×10¹⁹ atoms/cm³.

Further, the present invention relates to a method of fabricating a thin-film transistor including the following steps of:
forming a silicon oxide film layer for a substrate using TEOS as a material and by a plasma CVD method,
   forming an amorphous silicon film layer on the silicon oxide film layer,
applying a laser irradiation to the amorphous silicon film layer to form a semiconductor active layer of polycrystalline silicon,
forming a gate insulating film on the semiconductor active layer; and
forming a gate electrode insulated from the semiconductor active layer by the gate insulating film.

In the above method, the step of forming a silicon nitride film layer on the substrate is preferably provided before the step of forming a silicon oxide film layer.

According to the present invention, with a plasma CVD method using TEOS as a material, an insulating undercoating layer of a silicon oxide film having uniform and high crystallinity and being small in level is formed. Thus, it is possible to provide a thin-film transistor having reduced dispersion in threshold voltage and being excellent in display quality, reliability and electric properties.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A-1H are cross-sectional views showing an example of a thin-film transistor of the present invention.

FIG. 2 is a graph showing the threshold voltage of a thin-film transistor according to an example using TEOS-based gas as a material for a silicon oxide film layer.

FIG. 3 is a graph showing the threshold voltage of a thin-film transistor according to an example using SiH₄-based gas as a material for a silicon oxide film layer.

### DESCRIPTION OF THE PREFERRED EMBODIMENTS

The present invention is characterized in that an insulating undercoating layer is provided in order to prevent the reduction in voltage properties due to diffusion of an impurity from a substrate into a semiconductor active layer that is especially problematic when the substrate is a glass substrate. The insulating undercoating layer of the present invention is of a silicon oxide layer formed by a plasma CVD method using TEOS as a material.

The concentration of carbon atoms of the silicon oxide layer is preferably set within a range of 6×10¹⁹ atoms/cm³ to 1×10²⁰ atoms/cm³. The thin-film transistor properties significantly depend on the level of an undercoating layer, while, in the present invention, since TEOS is employed as a material for the silicon oxide film layer formed as an insulating undercoating layer, it is possible to form a silicon oxide film layer with less level than when employing SiH₄ and to reduce the threshold voltage and a value S. The concentration of carbon atoms of the silicon oxide film layer of at least 6×10¹⁹ atoms/cm³ ensures excellent electrical properties, and if the concentration is not more than 1×10²⁰ atoms/cm³, degradation in electrical properties due to production of silicon carbide is avoided.

The concentration of nitride atoms in the silicon oxide film layer of the present invention is preferably not more than 3×10¹⁹ atoms/cm³. In this case, the concentration of an impurity is limited under a predetermined value so that degradation in transistor properties due to variation in resistance value is avoided.

Further, it is especially preferable that the concentration of carbon atoms of the silicon oxide film layer is set within a range of 6×10¹⁹ atoms/cm³ to 1×10²⁰ atoms/cm³ and the concentration of nitride atoms is set to not more than 3×10¹⁹ atoms/cm³ since the threshold voltage in a thin-film transistor can be effectively reduced.

While the silicon oxide layer as an insulating undercoating layer may be formed directly on the substrate, another layer may be interposed between the substrate and the silicon oxide film layer. More specifically, it is preferable that after a silicon nitride film layer is formed on the substrate, the silicon oxide film layer is formed on the silicon nitride film layer. In this case, by forming a silicon nitride film layer with higher ability than the silicon oxide film layer to prevent diffusion of an impurity between the substrate and the silicon oxide film layer, increase in threshold voltage due to transfer of an impurity from the substrate to the semiconductor active layer is effectively prevented.

Preferable examples now will be described with reference to the drawings.

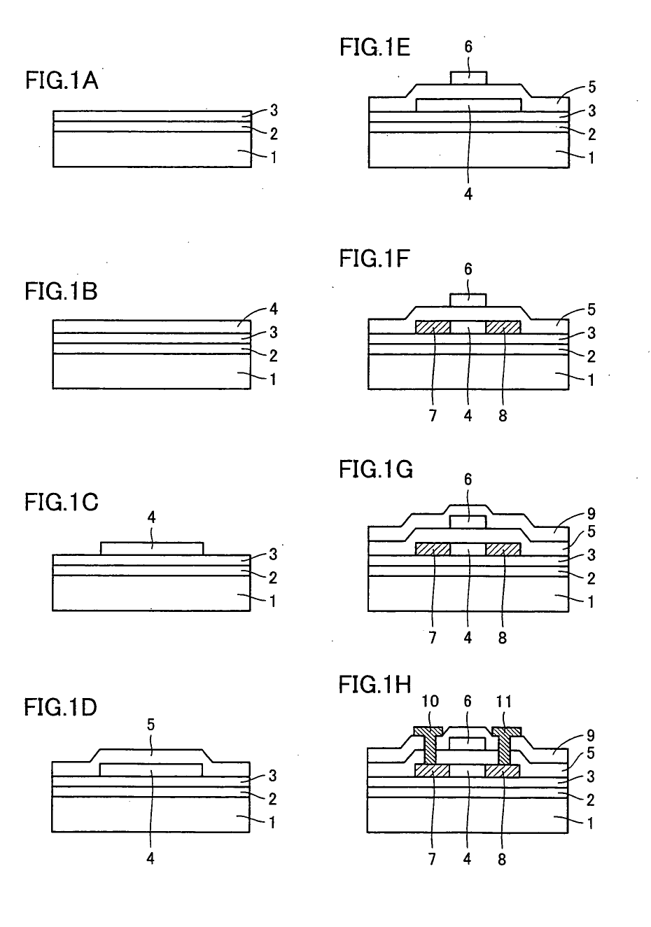

As shown in FIG. 1A, for example, a silicon nitride film layer 2 is formed on a substrate 1 such as a glass substrate and the like by a parallel-plate RF plasma CVD method and the like, and a silicon oxide film layer as an insulating undercoating layer 3 is formed on silicon nitride film layer 2 by a parallel-plate RF plasma CVD method. The silicon oxide film layer is formed of TEOS by feeding the TEOS in liquid state together with a gas as a source of oxygen into a chamber as a gaseous mixture, for example.

The thickness of silicon nitride film layer 2 can be made to at least 50 nm, for example. In this case, the silicon nitride film layer serves well as a diffusion barrier layer. The thickness of insulating undercoating layer 3 can be made to a range of 200 nm to 300 nm, for example. The thickness of the insulating undercoating layer is preferably at least 200 nm since diffusion of an impurity from the substrate to the semiconductor active layer is limited so that the threshold voltage of a thin-film transistor is effectively reduced. The thickness is preferably not more than 300 nm in terms of excellent productivity.

In the present invention, TEOS is employed as a material for a silicon oxide film layer formed as insulating undercoating layer 3. A silicon oxide film layer formed of TEOS is uniform in crystallinity and small in level so that the threshold voltage of a thin-film transistor can be reduced.

Then, an amorphous silicon film to make a semiconductor active layer is formed by a parallel-plate RF plasma CVD method and the like, as shown FIG. 1B. The thickness of the amorphous silicon film is preferably made to about 50 nm, for example. Making a grain size of silicon in the semiconductor active layer larger is effective to enhance carrier mobility, since the grain size of silicon has a maximal value for the film thickness of a silicon film layer, and forming a semiconductor active layer of a thickness of about 50 nm is particularly preferable to obtain good carrier mobility.

After the amorphous silicon film is formed, for example, a heat treatment is performed in an atmosphere of nitride to deaerate hydrogen within a film. Then, semiconductor active layer 4 of a polycrystalline silicon film is formed by applying XeCl excimer laser to the amorphous silicon film to cause it to melt and recrystallize for polycrystallization, for example.

Then, the polycrystalline silicon film is patterned by photolithography to form semiconductor active layer 4 of an island shaped polycrystalline silicon film of a thickness of about 50 nm, as shown in FIG. 1C. A silicon oxide film is then deposited on semiconductor active layer 4 by a plasma CVD method and the like to form a gate insulating film 5, as shown in FIG. 1D. At this time, the gate insulating film is preferably formed of TEOS. Subsequently, a film of, for example, Cr, Mo, W and the like of a thickness of at least 200 nm is formed on the gate insulating film by sputtering and the like, and is patterned by photolithography to make a gate electrode 6, as shown in FIG. 1E. If the thickness of the gate electrode is at least 200 nm, the risk that an ion penetrates the gate electrode is reduced when a source drain electrode is formed by ion doping.

Then, using gate electrode 6 as a mask, a source region 7 and a drain region 8 are formed, for example, by injecting phosphorus using an ion doping device or the like into semiconductor active layer 4 through gate insulating film 5 at an acceleration voltage of 50 keV and a dose of about 1.5×10¹⁵ atoms/cm², as shown FIG. 1F. The acceleration voltage and the dose in the injection of phosphorus are preferably set as appropriate to provide most effective injection of phosphorus into the semiconductor active layer. Too high concentration of phosphorus tends to result in high resistance of a doped semiconductor active layer due to amorphization of silicon crystals.

Then, annealing is performed again to activate a dopant impurity.

After a silicon oxide film is deposited by a plasma CVD method and the like and an interlayer insulating layer 9 is formed as shown in FIG. 1G, a contact hole is formed by patterning the interlayer insulating layer by photolithography. Preferably, interlayer insulating layer 9 is formed of TEOS.

Then, for example, wiring of Cr is deposited by sputtering and the like and is patterned by photolithography to form a source electrode 10 and a drain electrode 11, as shown in FIG. 1H.

Thus, a thin-film transistor according to the present invention is completed.

### EXAMPLE

The present invention now will be described with reference to examples, but it is not intended to be limited thereto.

(1) Forming of an Insulating Undercoating Layer

### EXAMPLE

On a glass substrate, a silicon nitride film layer was formed to a thickness of 50 nm and a silicon oxide film layer as an insulating undercoating layer was formed to a thickness of 200 nm by a parallel-plate RF plasma CVD method, respectively. Then, an amorphous silicon film layer was formed to a thickness of 50 nm by a parallel-plate RF plasma CVD method. In the present example, TEOS was used as a material for the insulating undercoating layer of a silicon oxide film and the amorphous silicon film layer. Subsequently, a heat treatment was performed in an atmosphere of nitride to deaerate hydrogen within a film, and the amorphous silicon film was then irradiated with XeCl excimer laser to make a polycrystalline silicon film.

Then, the polycrystalline silicon film was patterned by photolithography to form a semiconductor active layer of an island shaped polycrystalline silicon film of a thickness of 50 nm, and a silicon oxide film was deposited on the semiconductor active layer by a plasma CVD method to form a gate insulating film. Then, a Cr film was formed to a thickness of 200 nm on the gate insulating film by sputtering and was patterned by photolithography to form a gate electrode.

Then, using the gate electrode as a mask, phosphorus was injected by an ion doping device into the semiconductor active layer through the gate insulating film at an acceleration voltage of 50 keV and a dose of 1.5×10¹⁵ atoms/cm² to form a source region and a drain region. Subsequently, annealing was performed again to activate a dopant impurity.

Then, after a silicon oxide film was deposited by a plasma CVD method to form an interlayer insulating layer, a contact hole was formed by patterning the interlayer insulating layer by photolithography.

Then, Cr wiring was deposited by sputtering and was patterned by photolithography to form a source electrode and a drain electrode. Thus, a thin-film transistor was fabricated.

### REFERENCE EXAMPLE

A thin-film transistor was fabricated similarly except that SiH₄ was employed as a material for a silicon oxide film layer.

(2) Composition Analysis

Composition within the silicon oxide film layer formed as an insulating undercoating layer in the example and the reference example was analyzed by depth profile using SIMS (Secondary Ion Mass Spectroscopy). Table 1 shows the concentrations of carbon and nitride within the silicon oxide film layer. It is to be noted that each concentration value is shown as a minimum value to a maximum value to reflect dispersion in measurements in a region of the silicon oxide film layer.

TABLE 1

| | Example | Reference example |
|---|---|---|
| Concentration of | 6 × 10¹⁹˜10 × 10¹⁹ | 1 × 10¹⁸˜3 × 10¹⁸ |
| carbon (atoms/cm³) | | |
| Concentration of | 1 × 10¹⁹˜3 × 10¹⁹ | 4 × 10¹⁸˜7 × 10¹⁸ |
| nitride (atoms/cm³) | | |

(3) Measurement of the Threshold Voltage

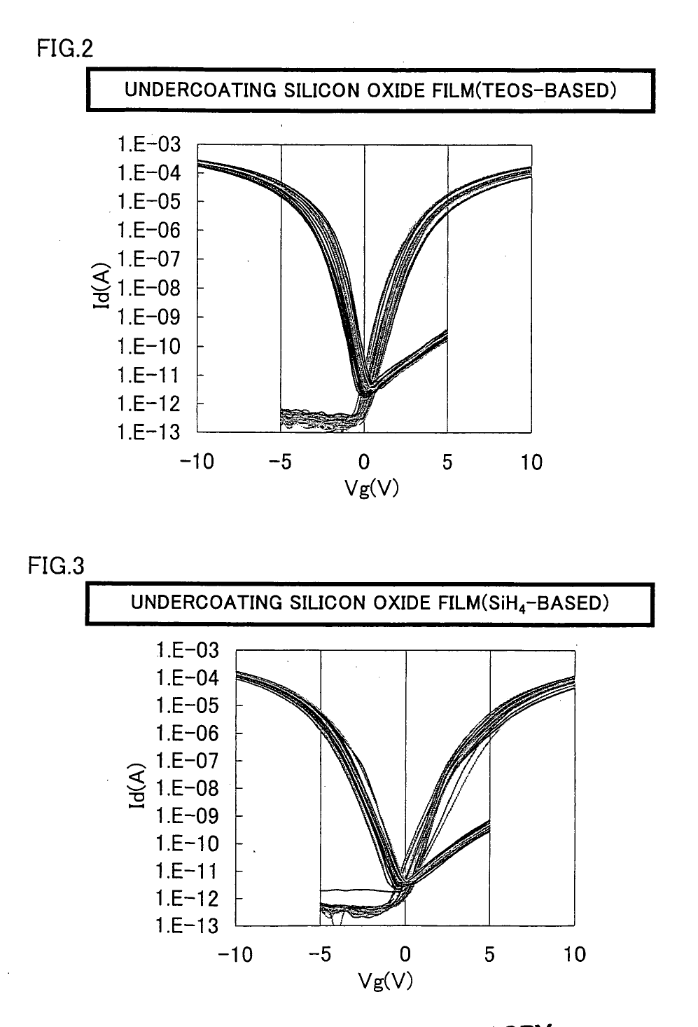

The threshold voltage was measured for the thin-film transistor fabricated in the example and the reference example. FIG. 2 shows the threshold voltage of the thin-film transistor according to the example using TEOS-based gas as a material for a silicon oxide film layer. FIG. 3 shows the threshold voltage of the thin-film transistor according to the reference example using SiH₄-based gas as a material for a silicon oxide film layer. Table 2 shows the threshold voltage calculated from FIGS. 2 and 3. It is to be noted that the threshold voltage when an n-channel polycrystalline thin-film transistor was made is shown as Vth (n) and the threshold voltage when a p-channel polycrystalline thin-film transistor was made is shown as Vth (p).

TABLE 2

| | | Reference |
|---|---|---|
| | Example | example |
| Vth(n) (V) | 3.2 | 4.7 |
| Vth(p) (V) | −2.6 | −4.5 |

The results in Table 1 shows that the concentration of carbon atoms of the silicon oxide film layer in the example was around 6×10¹⁹ to 10×10¹⁹ atoms/cm³ and the concentration of nitride atoms was around 1×10¹⁹ to 3×10¹⁹ atoms/cm³. On the other hand, the concentration of carbon atoms of the silicon oxide film layer in the reference example was around 1×10¹⁸ to 3×10¹⁸ atoms/cm³, and the concentration of nitride atoms was around 4×10¹⁸ to 7×10¹⁸ atoms/cm³.

The results in Table 2 shows that the threshold voltages Vth(n) and Vth (p) of the thin-film transistor in the example using TEOS as a material gas to form the silicon oxide film layer were 3.2 V and −2.6 V, respectively, significantly reduced compared with the threshold voltages Vth (n) and Vth (p) of the thin-film transistor of the reference example of 4.7 V and −4.5 V, respectively. Therefore, it was found that a thin-film transistor fabricated by a method of the present invention provides a concentration of carbon atoms and a concentration of nitride atoms set within a desired range and has excellent voltage properties.

Although the present invention has been described and illustrated in detail, it is clearly understood that the same is by way of illustration and example only and is not to be taken by way of limitation, the spirit and scope of the present invention being limited only by the terms of the appended claims.

1. A thin-film transistor comprising:
an insulating undercoating layer formed for a substrate;
a semiconductor active layer of polycrystalline silicon formed on said insulating undercoating layer; and
a gate electrode formed insulated on said semiconductor active layer;
wherein said insulating undercoating layer is of a silicon oxide film layer formed using tetraethoxysilane as a material and by a plasma CVD method.

2. The thin-film transistor of claim 1, wherein a concentration of carbon atoms of said silicon oxide film layer is within a range of 6×10¹⁹ atoms/cm³ to 1×10²⁰ atoms/cm³.

3. The thin-film transistor of claim 1, wherein a concentration of nitride atoms of said silicon oxide film layer is not more than 3×10¹⁹ atoms/cm³.

4. The thin-film transistor of claim 1, wherein a concentration of carbon atoms of said silicon oxide film layer is within a range of 6×10¹⁹ atoms/cm³ to 1×10²⁰ atoms/cm³ and a concentration of nitride atoms is not more than 3×10¹⁹ atoms/cm³.

5. A method of fabricating a thin-film transistor comprising the steps of:
forming a silicon oxide film layer for a substrate using tetraethoxysilane as a material and by a plasma CVD method;
forming an amorphous silicon film layer on said silicon oxide film layer;
applying a laser irradiation to said amorphous silicon film layer to form a semiconductor active layer of polycrystalline silicon;
forming an gate insulating film on said semiconductor active layer; and
forming a gate electrode insulated from said semiconductor active layer by said gate insulating film.

6. The method of fabricating a thin-film transistor of claim 5, wherein the step of forming a silicon nitride film layer on the substrate is provided before the step of forming said silicon oxide film layer.
